(19) United States
(12) Patent Application Publication
(10) Pub. No.: US 2024/0063230 A1
(43) Pub. Date: Feb. 22, 2024

(54) DISPLAY PANEL AND ELECTRONIC TERMINAL

(71) Applicant: Shenzhen China Star Optoelectronics Semiconductor Display Technology Co., Ltd., Shenzhen (CN)

(72) Inventor: Chuanbao LUO, Shenzhen (CN)

(21) Appl. No.: 18/051,051

(22) Filed: Oct. 31, 2022

(30) Foreign Application Priority Data
Aug. 19, 2022 (CN) 202211000809.5

(51) Int. Cl. H01L 27/12; H01L 29/417; H01L 29/786; H01L 29/66

(52) U.S. Cl. CPC H01L 27/124; H01L 27/1225; H01L 27/1248; H01L 29/41733; H01L 29/78633; H01L 29/7869; H01L 27/127; H01L 29/66969

(57) ABSTRACT

The present application provides a display panel, a manufacturing method of the display panel, and an electronic terminal. The present application includes, stacked from bottom to top, a driving circuit layer including a driving circuit, a planarization layer including a first planarization portion and a second planarization portion arranged in the same layer, an electrode layer including an electrode group, and a light emitting layer including a light emitting device. The first planarization portion is arranged at one side of the driving circuit close to the electrode layer, the second planarization portion is arranged at one side of the electrode group close to the driving circuit layer, and a thickness of the second planarization portion is greater than a thickness of the first planarization portion.

### FIELD OF DISCLOSURE

The present application relates to a field of display technology, in particular to a field of manufacturing technology of display panels, and specifically to display panels and electronic terminals.

### DESCRIPTION OF RELATED ART

Sub-millimeter light-emitting diode (mini LED) display technology and micron light-emitting diode (micro LED) display technology are widely used in small and medium-sized high-value-added displays, and have the advantages of high contrast ratios, high brightness, and being thin and light.

At present, in order to use less photomasks and achieve seamless splicing technology, there are less non-metallic layers used to separate metal layers in electronic terminals made with mini-LED display technology or micro-LED display technology, and a cover plate and a sealant are not omitted during an encapsulating process. As a result, the ambient moisture and oxygen can easily enter an active layer of a transistor device through an encapsulating structure and film layers, thereby reducing the operation reliability of the transistor device.

Therefore, conventional electronic terminals made with mini-LED display technology or micro-LED display technology have a high risk of failure/malfunction of transistor devices, and improvement is urgently needed.

### SUMMARY

The present application provides a display panel and an electronic terminal, so as to solve a technical problem that a transistor device has a high risk of failure/malfunction in conventional electronic terminals manufactured using mini-LED display technology or micro-LED display technology.

The present application provides a display panel, including:
a substrate;
an active layer disposed on the substrate, wherein the active layer includes a channel portion and two conductive portions located at two sides of the channel portion;
a first conductive layer disposed at one side of the active layer close to or away from the substrate, wherein the first conductive layer includes a gate electrode, and a projection of the gate electrode projected on the substrate overlaps with a projection of the channel portion projected on the substrate; and
a second conductive layer disposed at one side of the active layer away from the substrate, the second conductive layer including a source electrode connected to one of the conductive portions;
wherein the source electrode is disposed in a different layer from a drain electrode connected to the other one of the conductive portions, and a projection of the source electrode projected on the substrate overlaps with the projection of the gate electrode projected on the substrate.

The present application further provides an electronic terminal, wherein the electronic terminal includes the display panel mentioned above.

### Advantages of the Present Application

The present application provides a display panel and an electronic terminal, including: a substrate; an active layer disposed on the substrate, the active layer including a channel portion and conductive portions located on two sides of the channel portion; a first conductive layer disposed at one side of the active layer close to or away from the substrate, wherein the first conductive layer includes a gate, and a projection of the gate electrode projected on the substrate overlaps with a projection of the channel portion projected on the substrate; and a second conductive layer disposed at one side of the active layer away from the substrate, wherein the second conductive layer includes a source electrode connected to one of the conductive portions. The source electrode is disposed in a different layer from the drain electrode connected to the other one of the conductive portions, and the source electrode extends toward to the drain electrode, so that a projection of the source electrode projected on the substrate overlaps the projection of the gate electrode projected on the substrate. On the premise of ensuring the electrical insulation between the source electrode and the drain electrode, a projection of the source electrode projected on the active layer can also overlap the channel portion to cover more portions of the active layer and reduce a risk of failure/malfunction of the active layer caused by the entry of moisture.

### BRIEF DESCRIPTION OF DRAWINGS

The present application will be described with reference to the accompanying drawings. It should be noted that the drawings are merely for the purposes of illustrating some embodiments of the present disclosure, and a person having ordinary skill in this field can obtain other figures according to these figures without inventive work.

FIG. 1 is a schematic cross-sectional view of a display panel according to a first embodiment of the present application.

FIG. 2 is a schematic cross-sectional view of the display panel according to a second embodiment of the present application.

FIG. 3 is a schematic cross-sectional view of the display panel according to a third embodiment of the present application.

FIG. 4 is a schematic cross-sectional view of the display panel according to a fourth embodiment of the present application.

FIG. 5 is a schematic cross-sectional view illustrating a manufacturing method of the display panel according to one embodiment of the present application.

### DETAILED DESCRIPTION OF EMBODIMENTS

The technical solutions in the present application will be described clearly and completely below with reference to the accompanying drawings and in conjunction with specific embodiments. Obviously, the described embodiments are only some of the embodiments of the present application, but not all of the embodiments. Based on the embodiments in the present application, all other embodiments obtained by those skilled in the art without creative work fall within the protection scope of the present application.

The terms such as “first” and “second” in the present application are used to distinguish different objects, rather than to describe a specific order. Furthermore, the terms like “comprising”, “including”, and any variations thereof are intended to fully cover non-exclusive inclusion. For example, a process, method, system, product, or device comprising a series of steps or modules is not limited to the listed steps or modules, but optionally also includes unlisted steps or modules, or optionally also includes other steps or modules inherent to these processes, methods, products, or devices. It should be noted that the term “overlapping arrangement” used to describe two structures located at different layers in this application can be understood as that orthogonal projections of the corresponding two structures projected on the same plane overlap each other.

Reference herein to an “embodiment” means that a particular feature, structure, or characteristic described in connection with the embodiment can be included in at least one embodiment of the present application. This term appearing in various places in the specification does not necessarily refer to the same embodiment, nor separate or alternative embodiments that are exclusive of other embodiments. It is explicitly and implicitly understood by those skilled in the art that the embodiments described herein can be combined with other embodiments.

The present application provides a display panel, and the display panel includes, but is not limited to, the following embodiments and combinations of the following embodiments.

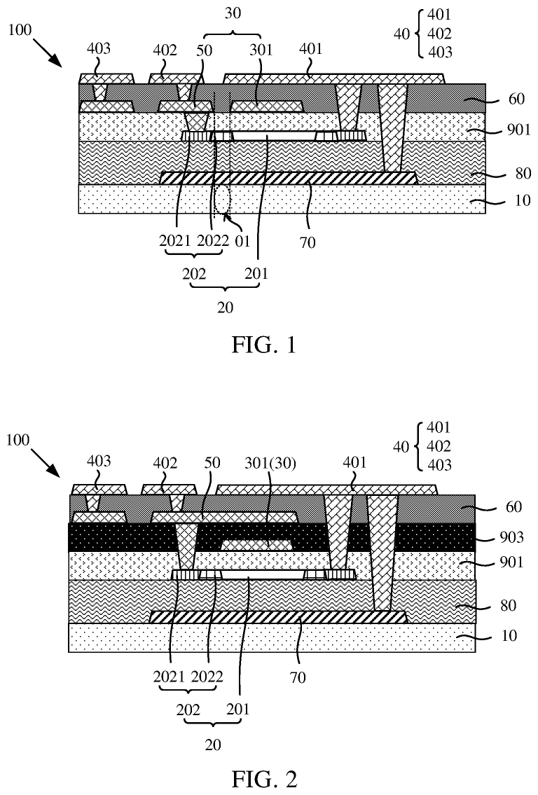

In one embodiment, as shown in FIG. 1 to FIG. 4, the display panel 100 includes: a substrate 10; an active layer 20 disposed on the substrate 10, wherein the active layer 20 includes a channel portion 201 and two conductive portions 202, and the two conductive portions 202 are disposed at two sides of the channel portion 201; a first conductive layer 30 disposed on one side of the active layer 20 close to or away from the substrate 10, wherein the first conductive layer 30 includes a gate electrode 301, the gate electrode 301 overlaps with the channel portion 201, and since the gate 301 and the channel portion 201 are not coplanar, it can also be understood that a projection of the gate electrode 301 projected on the substrate 10 overlaps with a projection of the channel portion 201 projected on the substrate 10; and a second conductive layer 40 disposed at one side of the active layer 20 away from the substrate 10, wherein the second conductive layer includes a source electrode 401 connected to one of the conductive portions 202, and the source electrode 401 is disposed in a different layer than a drain electrode 50 connected to the other one of the conductive portions 202. The source electrode 401 and the gate electrode 301 are arranged overlappingly. Since the source electrode 401 and the gate electrode are not coplanar, it can also be understood that a projection of the source electrode 401 projected on the substrate 10 overlaps with the projection of the gate electrode 301 projected on the substrate 10.

The substrate 10 can be a flexible substrate or a rigid substrate. A material of the active layer 20 can include a semiconductor material such as amorphous silicon, polysilicon, organic semiconductor materials, and metal oxides. The conductive portions 202 can be formed by doping particles including but not limited to hydrogen, phosphorus ions, or boron ions at two ends of the active layer 20. As shown in FIG. 1 and FIG. 2, the gate electrode 301 in the present embodiment can be disposed at one side of the active layer 20 and away from the substrate 10 to form a top gate structure. As shown in FIG. 4, the gate electrode 301 can also be disposed at one side of the active layer 20 and close to the substrate 10 to form a bottom gate structure. The gate electrode 301 has a voltage after a voltage is applied to the gate electrode 301, or it is considered that there is a voltage difference between the gate electrode 301 and the channel portion 201 in the active layer 20, so that an electric field is generated in a direction from the gate electrode 301 to the substrate 10 to drive electrons and holes in the active layer 20 to move in the channel portion 201, thereby electrically connecting the source electrode 401 and the drain electrode 50. It should be noted that the performance of the active layer 20 will be affected if moisture invades into the active layer 20, which reduces the reliability of operations of thin film transistors in the display panel 100.

Specifically, as shown in FIG. 1 to FIG. 4, the gate electrode 301 and the channel portion 201 overlap each other, the source electrode 401 is connected to one of the conductive portions 202 of the active layer 20, and the drain electrode 50 is connected to the other one of the conductive portions 202 of the active layer 20. That is to say, the source electrode 401 is disposed close to one of the conductive portions 202 of the active layer 20, and the drain electrode 50 is disposed close to the other one of the conductive portions 202 of the active layer 20. In other words, the gate electrode 301 is arranged close to a position between the source electrode 401 and the drain electrode 50. It can be understood that in the present embodiment, the source electrode 401 and the drain electrode 50 are arranged in different layers to achieve insulation between the two. Accordingly, the source electrode 401 extends to be close to the drain electrode 50 to overlap the gate electrode 301. As a result, on the premise of ensuring the insulation between the source electrode 401 and the drain electrode 50, the projection of the source electrode 401 projected on the active layer 20 can also overlap the channel portion 201 to cover more portions of the active layer 20, so that the present application can increase a size of the source electrode 401 for blocking the entry of moisture into the active layer 20 and reduce a risk of failure/malfunction of the active layer 20 caused by the entry of moisture.

In one embodiment, as shown in FIGS. 1 to 4, the projection of the source electrode 401 projected on the substrate 10 completely covers the projection of the gate electrode 301 projected on the substrate 10. Specifically, according to the above discussion, it can be known that the source electrode 401 extends toward the drain electrode 50 to overlap the gate electrode 301, which can cover more portions of the active layer 20. It can be understood that in the present embodiment, one end of the source electrode 401 close to the gate electrode 301 extends beyond one end of the gate electrode 301 away from the source electrode 401. That is to say, the source electrode 401 can completely cover the gate electrode 301. In other words, the source electrode 401 can completely cover the channel portion 201 to cover more portions of the active layer 20 in a direction away from the source electrode 401. As a result, the present application increases a size of the source electrode 401 for blocking the entry of moisture into the active layer 20, and reduces a risk of failure/malfunction of the active layer 20 caused by the entry of moisture.

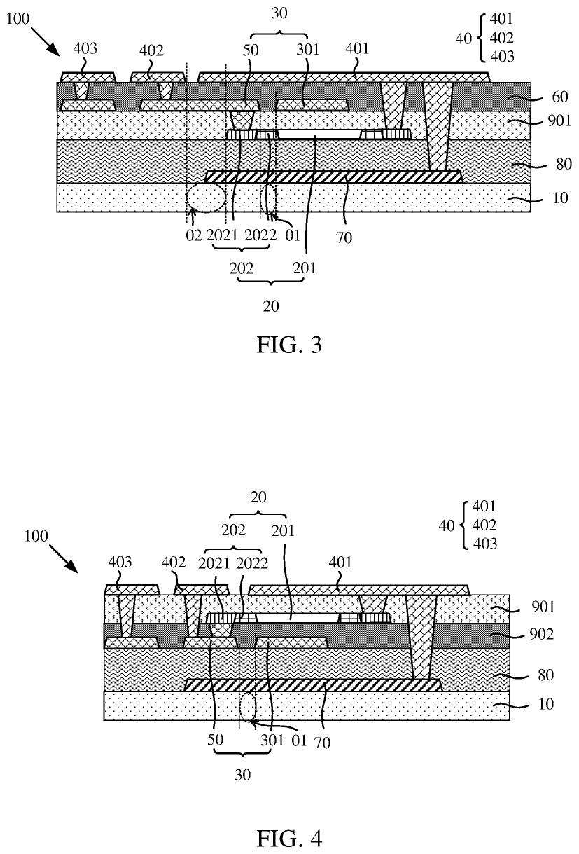

In one embodiment, as shown in FIG. 1, FIG. 3, and FIG. 4, the first conductive layer 30 further includes the drain electrode 50 which is in the same layer as and spaced apart from the gate electrode 301. A first gap 01 is defined between the projection of the drain electrode 50 projected on the substrate 10 and the projection of the gate electrode 301 projected on the substrate 10. Specifically, as shown in FIG. 1 for example, the gate electrode 301 is disposed at one side of the active layer 20 away from the substrate 10 to form the top gate structure. In the present embodiment, the drain electrode 50 is also disposed at one side of the active layer 20 away from the substrate 10. The drain electrode 50 is disposed in the same layer as and spaced apart from the gate electrode 301 to form the first conductive layer 30. Therefore, the source electrode 401 can also be extended toward the drain electrode 50 to overlap the gate electrode 301. In another example, as shown in FIG. 4, the gate electrode 301 is disposed at one side of the active layer 20 close to the substrate 10 to form the bottom gate structure. In the present embodiment, the drain 50 is also arranged at one side of the active layer 20 away from the substrate 10 and is arranged in the same layer as and spaced apart from the gate electrode 301 to form the first conductive layer 30. Such configuration can also extend the source electrode 401 toward the drain electrode 50 to overlap the gate electrode 301.

It can be understood that the drain electrode 50 and the gate electrode 301 in the present embodiment are in the same layer and spaced apart from each other. That is to say, both the drain electrode 50 and the gate electrode 301 are located on the same film layer. Further, the drain electrode 50 and the gate electrode 301 can be made of the same material. As a result, the same manufacturing process and the same photomask to form the first conductive layer 30 including the drain electrode 50 and the gate electrode 301, which saves the types of photomasks for manufacturing the display panel 100 and improves the manufacturing efficiency of the display panel 100. Specifically, based on the fact that the drain electrode 50 and the gate electrode 301 are in the same layer and spaced apart from each other, the same manufacturing process and the same photomask can be used to form the first conductive layer 30 including the drain electrode 50 and the gate electrode 301, so the drain electrode 50 and the gate electrode 301 can have lower resistance and higher conductivity.

In one embodiment, as shown in FIG. 1, FIG. 3, and FIG. 4, the projection of the source electrode 401 projected on the substrate 10 overlaps with the first gap 01. Specifically, based on the above discussion, it can be known that the gate electrode 301 and the channel portion 201 are overlapped with each other, and the gate electrode 301 is arranged close to a position between the source electrode 401 and the drain electrode 50. Based on the fact that the drain electrode 50 and the gate electrode 301 are arranged in the same layer and spaced apart from each other, it can be known that the first gap can overlap the active layer 20 or can be not overlapping the active layer 20. Further, in the present embodiment, the source electrode 401 extends toward the drain electrode 50 to overlap the first gap. It can be understood that the source electrode 401 shields the first gap on the premise of shielding the gate electrode 301, which can reduce a risk of moisture entering from the first gap. Therefore, the moisture entering the active layer 20 is reduced, and the risk of failure/malfunction of the active layer 20 due to entry of moisture is further reduced.

It should be noted that relative positions of the source electrode 401 and the first conductive layer 30 are not limited in the present embodiment. For example, the first conductive layer 30 can be disposed at one side of the source electrode 401 close to the substrate 10 (as shown in FIG. 1 and FIG. 4). Further, even in FIG. 4, the gate electrode 301 can be disposed at one side of the active layer 20 close to the substrate 10 to form the bottom gate structure. One end of the source electrode 401 close to the gate electrode 301 overlaps with the first gap, so that the size of the source electrode 401 for blocking the entry of moisture into the active layer 20 can still be increased. In another example, the first conductive layer 30 can be disposed at one side of the source electrode 401 away from the substrate 10, and the moisture entering from the first gap can be blocked in the second conductive layer 40 by the source electrode 401 which overlaps the first gap.

In one embodiment, as shown in FIG. 1 to FIG. 3, the first conductive layer 30 is disposed between the second conductive layer 40 and the active layer 20. The display panel 100 further includes: a passivation layer 60 disposed between the first conductive layer 30 and the second conductive layer 40, wherein each conductive portion 202 includes a first conductive portion 2021 and a second conductive portion 2022, the second conductive portion 2022 is disposed between the first conductive portion 2021 and the channel portion 201, a projection of the second conductive portion 2022 projected on the substrate 10 overlaps the first gap 01, and a concentration of hydrogen in the second conductive portion 2022 is greater than a concentration of hydrogen in the channel portion 201. The first gap 01 can enable the passivation layer 60 to provide hydrogen to the active layer 20. Specifically, the material of the passivation layer 60 can include, but is not limited to, silicon nitride, silicon oxide, and silicon oxynitride. The passivation layer 60 can allow hydrogen to diffuse. Further, the passivation layer 60 can also include hydrogen. It can be understood that the passivation layer 60 in the present embodiment is disposed between the first conductive layer 30 and the second conductive layer 40. That is to say, the first gap overlaps the passivation layer 60. The passivation layer 60 fills the first gap. While the passivation layer 60 separates and blocks the first conductive layer 30 from the second conductive layer 40, the passivation layer 60 combines with the first gap 01 to enable hydrogen to enter the active layer 20 through the passivation layer 60 and the first gap to realize conductivity of the active layer 20.

In particular, the elements doped in the first conductive portion 2021 and the second conductive portion 2022 in the present embodiment can be the same. For example, both the first conductive portion 2021 and the second conductive portion 2022 can be doped with hydrogen. Specifically, before the passivation layer 60 is formed, two ends of the active layer 20 can be doped with hydrogen to form the first conductive portion 2021 with the higher hydrogen concentration. After the passivation layer 60 is formed, hydrogen is doped through the first gap and the corresponding via structure to form the second conductive portion 2022 with the lower hydrogen concentration.

In one embodiment, as shown in FIG. 1 to FIG. 3, the present application further includes: a barrier layer disposed at one side of the passivation layer 60 away from the substrate 10, wherein the barrier layer is composed of at least one of aluminum oxide or titanium oxide. It can be understood that, since at least the first conductive layer 30 and the passivation layer 60 are disposed between the barrier layer and the active layer 20, such an arrangement can effectively prevent the active layer 20 from contacting the barrier layer formed by, but not limited to, at least one of aluminum oxide or titanium oxide.

In one embodiment, as shown in FIG. 1 to FIG. 4, the second conductive layer 40 further includes a first electrode portion 402 that is in the same layer as and space apart from the source electrode 401. The first electrode portion 402 is connected to the drain electrode 50. As shown in FIG. 3, a second gap 02 is defined between a projection of the first electrode portion 402 projected on the substrate 10 and the projection of the active layer 20 projected on the substrate 10. The projection of the source electrode 401 projected on the substrate 10 overlaps the second gap 02. Specifically, the first electrode portion 402 and the active layer 20 defines the second gap 02 in the horizontal direction. For example, as shown in FIG. 3, the drain electrode 50 can extend to overlap the first electrode portion 402, and a conductive substance can be filled in a via defined in the passivation layer 60 and arranged in an overlapping position between the drain electrode 50 and the first electrode part 402 to connect the drain electrode 50 and the first electrode portion 402. In another example, when the drain electrode 50 and the first electrode portion 402 overlaps each other, a via can also be defined in the passivation layer 60 to connect the drain electrode 50 and the first electrode portion 402, and the via is filled with a conductive substance to connect the drain electrode 50 and the first electrode portion 402.

It can be understood that in the present embodiment, the first electrode portion 402 and the active layer 20 are arranged to define the second gap 02 in the horizontal direction. Similarly, the first electrode portion 402 and the source electrode 401 can be made of the same material, so that the second conductive layer 40 including the first electrode portion 402 and the source electrode 401 can be formed using the same manufacturing process and the same photomask, which saves the types of photomasks for manufacturing the display panel 100 and improves the manufacturing efficiency of the display panel 100. Further, one end of the source electrode 401 close to the gate electrode 301 overlaps the second gap 02. That is to say, the source electrode 401 is arranged in a continuous manner and extends to completely cover the active layer 20, so that a portion of the second conductive layer 40 overlapping with the active layer 20 is fully occupied by the continuously arranged source electrode 401, which further improves the ability of the source electrode 401 in blocking the entry of moisture into the active layer 20 and further reduces the risk of failure/malfunction of the active layer 20.

In one embodiment, as shown in FIG. 1 to FIG. 4, the material of the source electrode 401 and the material of the first electrode portion 402 both include at least one of metal or metal oxide. Specifically, the display panel 100 can further include a second electrode portion 403 and a light emitting device. The light emitting device is electrically connected between the second electrode portion 403 and the first electrode portion 402. For example, as shown in FIG. 1 to FIG. 4, the first electrode portion 402 and the second electrode portion 403 can be arranged in the same layer and spaced apart from each other, and the light emitting device can be located on a same side with respect to the first electrode portion 402 and the second electrode portion 403 to emit light. An anode of the light emitting device can contact and be connected to the first electrode portion 402, and a cathode of the light emitting device can contact and be connected to the second electrode portion 403, so that the light emitting device can emit light under the action of a driving current generated by a voltage of the first electrode portion 402 and a voltage of the second electrode portion 403. In another example, the second electrode portion 403 can be disposed at one side of the first electrode portion 402 away from the substrate 10, and the light emitting device can be disposed between the first electrode portion 402 and the second electrode portion 403. Similarly, an anode of the light emitting device can contact and be connected to the first electrode portion 402, and a cathode of the light emitting device can contact and be connected to the second electrode portion 403, so that the light emitting device emits light under the action of a driving current generated by a voltage of the first electrode portion 402 and a voltage of the second electrode portion 403.

Specifically, based on the above discussion, the first electrode portion 402 and the source electrode 401 arranged spaced apart in the same layer can be made of the same material. Further, the material of the source electrode 401 and the material of the first electrode portion 402 in the present embodiment both include metal or metal oxide. For example, when the materials of the source electrode 401 and the first electrode portion 402 both include metal, they can have higher barrier ability to further improve the barrier ability against moisture, and can also have higher conductivity. In another example, when the materials of the source electrode 401 and the first electrode portion 402 include metal oxide, they can have lower reflectivity, so as to reduce a risk of reflecting external light to, but is not limited to, the light emitting device, so as to improve the reliability and stability of a display image of the display panel 100.

In one embodiment, as shown in FIG. 2, the drain electrode 50 and the source electrode 401 are both disposed in a different layer from the gate electrode 301, and the drain electrode 50 and the gate electrode 301 overlap each other. Specifically, based on the above discussion, the source electrode 401 and the drain electrode 50 are arranged in different layers to achieve isolation between the two. Based on this, the source electrode 401 extends toward the drain electrode 50 to overlap the gate electrode 301. Further, a size of the source electrode 401 for blocking the entry of moisture into the active layer 20 can be increased, thereby reducing the risk of failure/malfunction of the active layer 20 due to the entry of moisture.

It can be understood that in the present embodiment, the drain electrode 50, the source electrode 401, and the gate electrode 301 are further arranged in different layers, and the drain electrode 50 also extends toward the source electrode 401 to overlap the gate electrode 301. Similarly, in this way, on the premise that the gate electrode 301, the source electrode 401, and the drain electrode 50 are electrically insulated from each other, a projection of the drain electrode 50 projected on the active layer 20 can also overlap the channel portion 201 to cover more portions of the active layer 20. As a result, the present application can increase the size of the drain electrode 50 for blocking the entry of moisture into the active layer 20, and reduce the risk of failure/malfunction of the active layer 20 caused by the entry of moisture.

For example, as shown in FIG. 2, the display panel 100 further includes: a first gate insulating layer 901 disposed between the active layer 20 and the first conductive layer 30; an insulating layer 903 disposed between the first conductive layer 30 and the second conductive layer 40, wherein the drain electrode 50 is disposed between the insulating layer 903 and the second conductive layer 40; the passivation layer 60 disposed between the drain electrode 50 and the second conductive layer 40. The projection of the drain electrode 50 projected on the substrate 10 overlaps with the projection of the gate electrode 301 projected on the substrate 10.

Furthermore, as shown in FIG. 2, one end of the source electrode 401 close to the drain electrode 50 overlaps one end of the gate electrode 301 away from the source electrode 401, and one end of the drain electrode 50 close to the source electrode 401 overlaps one end of the gate electrode 301 close to the source electrode 401. That is to say, the projection of the source electrode 401 projected on the substrate 10 completely covers the projection of the gate electrode 301 projected on the substrate 10. The projection of the drain electrode 50 projected on the substrate 10 completely covers the projection of the gate electrode 301 projected on the substrate 10. Specifically, based on the above discussion, in the present embodiment, the source electrode 401 extends toward the drain electrode 50 to overlap the gate electrode 301, and the drain electrode 50 extends toward the source electrode 401 to overlap the gate electrode 301. That is to say, both the source electrode 401 and the drain electrode 50 can completely cover the channel portion 201 to cover more portions of the active layer 20, which further increases the size of the source electrode 401 for blocking the entry of moisture into the active layer 20 and reduces the risk of failure/malfunction of the active layer 20 caused by the entry of moisture.

In one embodiment, as shown in FIG. 1 to FIG. 4, the display panel 100 further includes: a light shielding layer 70 disposed at one side of the active layer 20 close to the substrate 10. A projection of the light shielding layer 70 projected on the substrate 10 covers the projection of the active layer 20 projected on the substrate 10. One end of the light shielding layer 70 is connected to at least one of the source electrode 401 or the drain electrode 50. Specifically, the display panel 100 can further include a buffer layer 80 disposed between the light shielding layer 70 and the active layer 20. As shown in FIGS. 1 to 3, based on the top gate structure, the display panel 100 can further include a first gate insulating layer 901 between the active layer 20 and the top gate electrode 301. Further, as shown in FIG. 2, due to the fact that the gate electrode 301 and the drain electrode 50 are disposed in different layers, an insulating layer 903 can also be disposed between the gate electrode 301 and the drain electrode 50. Alternatively, as shown in FIG. 4, based on the bottom gate structure, the display panel 100 can further include a second gate insulating layer 902 disposed between the active layer 20 and the bottom gate electrode 301.

The relative positional relationship between the source electrode 401 and the drain electrode 50 is not limited in the present embodiment. Basically, the source electrode 401 is disposed close to one conductive portion 202 in the active layer 20, and the drain electrode 50 is disposed close to the other conductive portion 202 in the active layer 20. In the present embodiment, a side portion of the light shielding layer 70 is connected to at least one of the source electrode 401 or the drain electrode 50. Based on the above discussion, a first gate insulating layer 901, an insulating layer 903, and a second gate insulating layer 902 are provided with via holes connected to the side portion of the light shielding layer 70 and at least one of the source electrode 401 or the drain electrode 50. The via holes are filled with conductive substances to electrically connect the light shielding layer 70 to at least one of the source electrode 401 and the drain electrode 50.

Specifically, in terms of the light shielding layer 70 mentioned above as shown in FIG. 1 to FIG. 4, alternatively, the drain electrode 50 can also be in the same layer as the light shielding layer 70. On the premise that the drain electrode 50, the source electrode 401, and the gate electrode 301 are arranged in different layers, it can be understood that if the drain electrode 50 and the light shielding layer 70 are arranged in the same layer, the present application can avoid adding film layers to insulate the drain electrode 50 and at least one of the source electrode 401 and the gate electrode 301. Also, the present application can reduce the risk of failure of the active layer 20 caused by the entry of moisture, and realize lightness and thinness of the display panel 100.

It can be understood that, based on the above discussion, the conductive substance in the via hole connected to the light shielding layer 70 and at least one of the source electrode 401 and the drain electrode 50 in the present embodiment can shield side portions of the active layer 20 to reduce the risk of moisture entering the active layer 20 from the side, the conductive substance forms an equipotential with the light-shielding layer 70 and at least one of the source electrode 401 and the drain electrode 50, which can shield an additional electric field generated by moisture molecules adsorbed on a surface of the active layer 20, and prevent the additional electric field from accelerating corrosion of the active layer 20.

The present application also provides a manufacturing method of a display panel, which can include, but is not limited to, the following steps and a combination of the following steps.

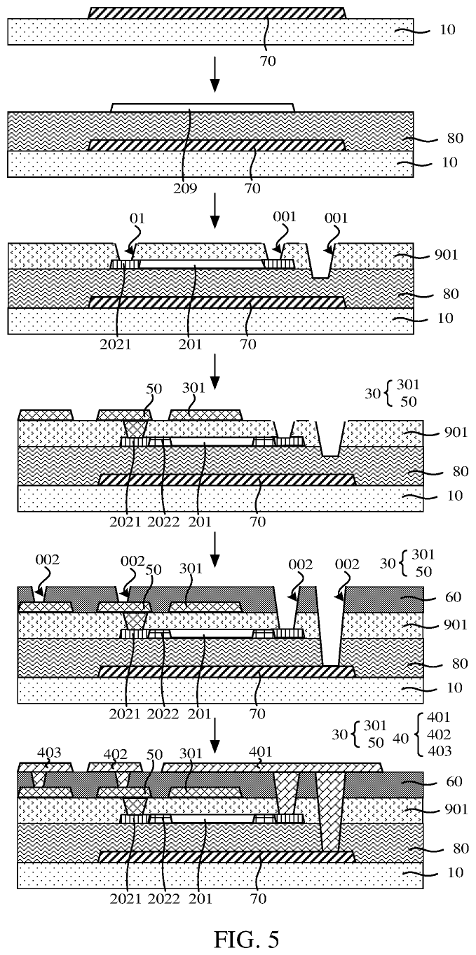

FIG. 5 is a schematic view of the manufacturing method of the display panel.

S1: forming a light shielding layer 70 on a substrate 10 by patterning.

The substrate 10 and the light shielding layer 70 can refer to the above related descriptions. Specifically, the light shielding layer 70 can be a single-layer film made of Mo, or an “A/B” type composite film layer or an “A/B/C” type composite film layer made of various materials, wherein A is located on B, and B is located on C. For example, the light shielding layer 70 can be, but not limited to, an Mo/Al film layer, an Mo/Cu film layer, an MoTi/Cu film layer, an MoTi/Cu/MoTi film layer, a Ti/Al/Ti film layer, a Ti/Cu/Ti film layer, an Mo/Cu/IZO film layer, an IZO/Cu/IZO film layer, or an Mo/Cu/ITO film layer.

S2: forming a buffer layer 80 on the light shielding layer 70 and the substrate 10, and forming a semiconductor layer 209 on the buffer layer 80 by patterning.

The buffer layer 80 can refer to the above related description. Specifically, the buffer layer 80 can be produced by chemical vapor deposition. For example, the buffer layer 80 can be a single-layer film layer made of silicon oxide, or can include a single-layer film layer made of silicon oxide, and a single-layer film made of silicon nitride disposed on the single-layer film made of silicon oxide. A material of the semiconductor layer 209 can include, but is not limited to, metal oxides with low leakage current, such as IGZO, IGTO, IGZO, IGO, IZO, AIZO, or ATZO.

S3: forming a first gate insulating film on the buffer layer 80 and the semiconductor layer 209, and patterning the first gate insulating film at positions corresponding to two ends of the semiconductor layer 209 to form three first holes 001 at positions corresponding to a side portion of the light shielding layer 70 to form the first gate insulating layer 901, and performing a conductorization process on two sides of the semiconductor layer 209 through the two first holes 001 on two sides of the semiconductor layer 209 to form the first conductive portion 2021.

For details about the first gate insulating layer 901 and the first conductive portion 2021, reference can be made to the above related descriptions. Specifically, the first gate insulating layer 901 can be a single-layer film layer made of silicon oxide or silicon nitride, or an “A/B” type composite film made of various materials, or an “A/B/C” type composite film layer, wherein A is located on B, and B is located on C. For example, the first gate insulating layer 901 can be, but not limited to, Al₂O₃/SiNx/SiOx film layer or SiOx/SiNx/SiOx film layer. The conductorization process can be, but not limited to, doping with hydrogen. Further, the three first holes 001 formed corresponding to the side portion of the light shielding layer 70 can also extend into the buffer layer 80.

S4: forming a first conductive layer 30 on the first gate insulating layer 901 by patterning, wherein the first conductive layer 30 includes a gate electrode 301 and a drain electrode 50.

For details about the first conductive layer 30, the gate electrode 301, and the drain electrode 50, reference can be made to the above related descriptions. Specifically, the first conductive layer 30 can be a single-layer film layer made of Mo, or an “A/B” type composite film layer, or an “A/B/C” type composite film layer made of various materials, wherein A is located on B, and B is located on C. For example, the first conductive layer 30 can be, but not limited to, an Mo/Al film layer, an Mo/Cu film layer, an MoTi/Cu film layer, an MoTi/Cu/MoTi film layer, a Ti/Al/Ti film layer, a Ti/Cu/Ti film layer, an Mo/Cu/IZO film layer, an IZO/Cu/IZO film layer, or an Mo/Cu/ITO film layer.

S5: forming a passivation film on the first conductive layer 30 and the first gate insulating layer 901, and forming three second holes 002 in a passivation film by patterning in the passivation film at least a portion corresponding to the drain electrode 50 and portions corresponding to the other two first holes 001 to form the passivation layer 60.

For details about the passivation layer 60, reference can be made to the above related descriptions. Specifically, the passivation layer 60 can be a single-layer film layer made of silicon oxide, silicon nitride, or silicon oxynitride, or an “A/B” type composite film made of various materials, wherein A is located on B. For example, the passivation layer 60 can be, but not limited to, SiNx/SiOx. Specifically, the active layer 20 can be performed a conductorization process by having hydrogen diffusion in the passivation film first to form the second conductive portion 2022, and then the patterning process can be performed to form the at least three second holes 002.

S6: forming a second conductive layer 40 on the passivation layer 60 by patterning, and the second conductive layer 40 includes a first electrode portion 402, a second electrode portion 403, and a source electrode 401.

About details about the first electrode portion 402, the second electrode portion 403, and the source electrode 401, reference can be made to the above related descriptions. Specifically, the second conductive layer 40 can be a single-layer film layer made of ITO or IZO, or an “A/B” type composite film layer or an “A/B/C” type composite film layer made of various materials, wherein A is located on B, and B is located on C. For example, the second conductive layer 40 can be, but not limited to, an ITO/Ag/ITO film layer, an IZO/Ag/IZO film layer, an Mo/Cu film layer, or an MoTi/Cu/MoTi film layer.

The present application further provides an electronic terminal, and the electronic terminal includes any display panel described above.

The present application provides a display panel and an electronic terminal, including: a substrate; an active layer disposed on the substrate, the active layer including a channel portion and conductive portions located on two sides of the channel portion; a first conductive layer disposed at one side of the active layer close to or away from the substrate, wherein the first conductive layer includes a gate, and a projection of the gate electrode projected on the substrate overlaps with a projection of the channel portion projected on the substrate; and a second conductive layer disposed at one side of the active layer away from the substrate, wherein the second conductive layer includes a source electrode connected to one of the conductive portions. The source electrode is disposed in a different layer from the drain electrode connected to the other one of the conductive portions, and the source electrode extends toward to the drain electrode, so that a projection of the source electrode projected on the substrate overlaps the projection of the gate electrode projected on the substrate. On the premise of ensuring the electrical insulation between the source electrode and the drain electrode, a projection of the source electrode projected on the active layer can also overlap the channel portion to cover more portions of the active layer and reduce a risk of failure/malfunction of the active layer caused by the entry of moisture.

The display panel and electronic terminal of the present application have been described in detail above. Working principles and embodiments of the present application are described in the present disclosure with specific examples. The descriptions of the above embodiments are only for ease of understanding technical solutions and main ideas of the present application. Those of ordinary skill in the art should understand that they can still modify the technical solutions described in the foregoing embodiments, or perform equivalent replacements to some of the technical features. Such modifications or replacements are within the protection scope of the technical solutions of the present application.

What is claimed is:

1. A display panel, comprising:
a substrate;
an active layer disposed on the substrate, wherein the active layer comprises a channel portion and two conductive portions located at two sides of the channel portion;
a first conductive layer disposed at one side of the active layer close to or away from the substrate, wherein the first conductive layer comprises a gate electrode, and a projection of the gate electrode projected on the substrate overlaps with a projection of the channel portion projected on the substrate; and
a second conductive layer disposed at one side of the active layer away from the substrate, the second conductive layer comprising a source electrode connected to one of the conductive portions;
wherein the source electrode is disposed in a different layer from a drain electrode connected to the other one of the conductive portions, and a projection of the source electrode projected on the substrate overlaps with the projection of the gate electrode projected on the substrate;
wherein the projection of the source electrode projected on the substrate completely covers the projection of the gate electrode projected on the substrate; and
wherein the first conductive layer further comprises the drain electrode which is in the same layer as and spaced apart from the gate electrode, and a first gap is defined between a projection of the drain electrode projected on the substrate and the projection of the gate electrode projected on the substrate.

2. The display panel according to claim 1, wherein the projection of the source electrode projected on the substrate overlaps the first gap.

3. The display panel according to claim 1, wherein the first conductive layer is disposed between the second conductive layer and the active layer, and the display panel further comprises:
a passivation layer disposed between the first conductive layer and the second conductive layer;
wherein each of the conductive portions comprises a first conductive portion and a second conductive portion, the second conductive portion is disposed between the first conductive portion and the channel portion, a projection of the second conductive portion projected on the substrate overlaps the first gap, and a concentration of hydrogen in the second conductive portion is higher than a concentration of hydrogen in the channel portion.

4. The display panel according to claim 3, further comprising:
a barrier layer disposed on one side of the passivation layer away from the substrate, wherein a material of the barrier layer comprises at least one of aluminum oxide or titanium oxide.

5. The display panel according to claim 1, wherein the second conductive layer further comprises a first electrode portion which is in the same layer as and spaced apart from the source electrode, and the first electrode portion is connected to the drain electrode; and
wherein a second gap is defined between a projection of the first electrode portion projected on the substrate and a projection of the active layer projected on the substrate, and the projection of the source electrode projected on the substrate overlaps the second gap.

6. The display panel according to claim 5, wherein a material of the source electrode and a material of the first electrode portion both comprise at least one of metal or metal oxide.

7. The display panel according to claim 1, further comprising:
a first gate insulating layer disposed between the active layer and the first conductive layer;
an insulating layer disposed between the first conductive layer and the second conductive layer, wherein the drain electrode is disposed between the insulating layer and the second conductive layer; and
a passivation layer disposed between the drain electrode and the second conductive layer;
wherein a projection of the drain electrode projected on the substrate overlaps with the projection of the gate electrode projected on the substrate.

8. A display panel, comprising:
a substrate;
an active layer disposed on the substrate, wherein the active layer comprises a channel portion and two conductive portions located at two sides of the channel portion;
a first conductive layer disposed at one side of the active layer close to or away from the substrate, wherein the first conductive layer comprises a gate electrode, and a projection of the gate electrode projected on the substrate overlaps with a projection of the channel portion projected on the substrate; and
a second conductive layer disposed at one side of the active layer away from the substrate, the second conductive layer comprising a source electrode connected to one of the conductive portions;
wherein the source electrode is disposed in a different layer from a drain electrode connected to the other one of the conductive portions, and a projection of the source electrode projected on the substrate overlaps with the projection of the gate electrode projected on the substrate.

9. The display panel according to claim 8, wherein the projection of the source electrode projected on the substrate completely covers the projection of the gate electrode projected on the substrate.

10. The display panel according to claim 8, wherein the first conductive layer further comprises the drain electrode which is in the same layer as and spaced apart from the gate electrode, and a first gap is defined between a projection of the drain electrode projected on the substrate and the projection of the gate electrode projected on the substrate.

11. The display panel according to claim 10, wherein the projection of the source electrode projected on the substrate overlaps the first gap.

12. The display panel according to claim 10, wherein the first conductive layer is disposed between the second conductive layer and the active layer, and the display panel further comprises:
a passivation layer disposed between the first conductive layer and the second conductive layer;
wherein each of the conductive portions comprises a first conductive portion and a second conductive portion, the second conductive portion is disposed between the first conductive portion and the channel portion, a projection of the second conductive portion projected on the substrate overlaps the first gap, and a concentration of hydrogen in the second conductive portion is higher than a concentration of hydrogen in the channel portion.

13. The display panel according to claim 12, further comprising:
a barrier layer disposed on one side of the passivation layer away from the substrate, wherein a material of the barrier layer comprises at least one of aluminum oxide or titanium oxide.

14. The display panel according to claim 8, wherein the second conductive layer further comprises a first electrode portion which is in the same layer as and spaced apart from the source electrode, and the first electrode portion is connected to the drain electrode; and
wherein a second gap is defined between a projection of the first electrode portion projected on the substrate and a projection of the active layer projected on the substrate, and the projection of the source electrode projected on the substrate overlaps the second gap.

15. The display panel according to claim 14, wherein a material of the source electrode and a material of the first electrode portion both comprise at least one of metal or metal oxide.

16. The display panel according to claim 8, further comprising:
a first gate insulating layer disposed between the active layer and the first conductive layer;
an insulating layer disposed between the first conductive layer and the second conductive layer, wherein the drain electrode is disposed between the insulating layer and the second conductive layer; and
a passivation layer disposed between the drain electrode and the second conductive layer;
wherein a projection of the drain electrode projected on the substrate overlaps with the projection of the gate electrode projected on the substrate.

17. The display panel according to claim 16, wherein the projection of the source electrode projected on the substrate completely covers the projection of the gate electrode projected on the substrate, and the projection of the drain electrode projected on the substrate completely covers the projection of the gate electrode projected on the substrate.

18. The display panel according to claim 8, further comprising:
a first gate insulating layer disposed between the active layer and the first conductive layer;
a passivation layer disposed between the first conductive layer and the second conductive layer; and
a light shielding layer disposed at one side of the active layer close to the substrate, wherein a projection of the light shielding layer projected on the substrate covers a projection of the active layer projected on the substrate;
wherein the drain electrode and the light shielding layer are arranged in the same layer.

19. The display panel according to claim 8, further comprising:
a light shielding layer disposed at one side of the active layer close to the substrate, wherein a projection of the light shielding layer projected on the substrate covers a projection of the active layer projected on the substrate, and one end of the light shielding layer is connected to at least one of the source electrode or the drain electrode.

20. An electronic terminal, wherein the electronic terminal comprises the display panel of claim 8.
